(19) United States
(12) Patent Application Publication
(10) Pub. No.: US 2012/0052438 A1
(43) Pub. Date: Mar. 1, 2012

(54) PHOTORESIST COMPOSITION AND METHOD OF FORMING PATTERN USING THE SAME

(76) Inventors: Cha-Dong KIM, Hwaseong-si (KR); Sang-Hyun Yun, Suwon-si (KR); Jung-In Park, Suwon-si (KR); Hi-Kuk Lee, Yongin-si (KR); Deok-Man Kang, Seongnam-si (KR); Youn-Suk Kim, Yongin-si (KR); Sae-Tae Oh, Pyeongtack-si (KR)

(21) Appl. No.: 13/117,032

(22) Filed: May 26, 2011

(30) Foreign Application Priority Data
Sep. 1, 2010 (KR) 10-2010-0085516

(51) Int. Cl. G03F 7/004; G03F 7/20

(52) U.S. Cl. 430/270.1; 430/323

(57) ABSTRACT

A photoresist composition and method of forming pattern using the same are provided. The photoresist composition contains an alkali-soluble novolac resin, a photosensitizer including a compound of Chemical Formula 1, and a solvent.

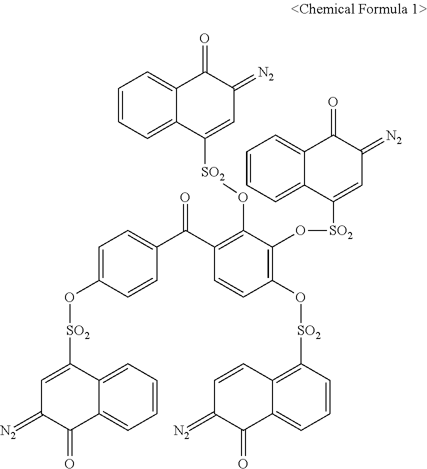

This application claims priority from Korean Patent Application No. 10-2010-0085516 filed on Sep. 1, 2010 in the Korean Intellectual Property Office, and all the benefits accruing therefrom under 35 U.S.C. 119, the contents of which in its entirety are herein incorporated by reference.

### BACKGROUND

1. Field of the Invention

The present invention relates to a photoresist composition and a method of forming a pattern using the same.

2. Description of the Related Art

In general, in the process of fabricating a printed circuit board, a semiconductor wafer, a liquid crystal display panel or the like, complicated circuit patterns are formed on a base substrate, such as an insulating substrate and/or a glass substrate. Photolithography is widely used to form such circuit patterns.

In photolithography, a photoresist film is formed on the base substrate, and the photoresist film is exposed to light by using a photomask having a transfer pattern corresponding to a circuit pattern. The photomask is very finely fabricated using very expensive equipment. Accordingly, research is being conducted on exposure methods for photoresist films that reduce or eliminate the use of photomasks.

An example of an exposure method that does not use a photomask includes a digital exposure method for controlling on/off operations of an exposure beam in a digital system that correspond to respective pixels of the transfer pattern. The digital exposure method is a method of forming a pattern on a substrate by spatially modulating and controlling light, wherein millions of micromirrors in a spatial optical modulator are instantly driven to selectively reflect light emitted from a light source.

In case of the digital exposure method, an h-line laser diode is used instead of a general high-pressure mercury lamp to prevent degradation of digital micromirrors that are made of aluminum. The h-line light may refer to light having a wavelength of about 405 nm. In order to form a pattern having excellent linearity by using the digital exposure method, it is necessary to develop a photoresist composition having high sensitivity for h-line light.

### SUMMARY

A photoresist composition suitable for forming a photoresist pattern having excellent linearity is provided.

A method of forming a pattern using a photoresist composition suitable for forming a photoresist pattern having excellent linearity is also provided.

According to one aspect, there is provided a photoresist composition including an alkali-soluble novolac resin, a photosensitizer including a compound of Chemical Formula 1, and a solvent.

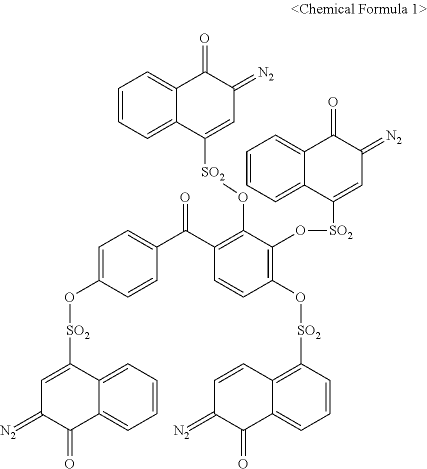

According to another aspect, there is provided a method of forming a pattern including forming a photoresist film by coating a pattern formation film with a photoresist composition containing an alkali-soluble novolac resin, a photosensitizer including a compound of Chemical Formula 1, and a solvent, exposing the photoresist film to light, developing the photoresist film to form a photoresist pattern, and patterning the pattern formation film using the photoresist pattern as an etching mask.

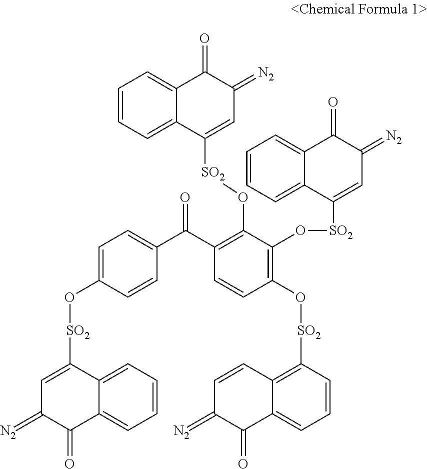

Other aspects of the present invention are included in the description and drawings.

### BRIEF DESCRIPTION OF THE DRAWINGS

The above and other aspects and features will become more apparent by describing exemplary embodiments thereof with reference to the attached drawings, in which:

FIG. 1 illustrates the absorbance of the compound of Chemical Formula 2 as a function of the wavelength band;

FIG. 2 illustrates a perspective view showing a digital exposure device used in forming a pattern in accordance with an embodiment;

FIG. 3 is a block diagram showing a specific configuration of an exposure head shown in FIG. 2;

FIGS. 4 to 7 illustrate cross sectional views showing the steps of the method of forming a pattern in accordance with an embodiment;

FIG. 8 illustrates a layout of the thin film transistor substrate fabricated by the fabricating method in accordance with an embodiment;

FIG. 9 illustrates a cross sectional view of the thin film transistor substrate, which is taken along line B-B′ of FIG. 8;

FIGS. 10A, 10B, 11A, 11,B, 12, 13, 14A and 14B illustrate cross sectional views for explaining a method of fabricating a display device of FIG. 8;

FIG. 15A illustrates an SEM photograph showing the photoresist pattern formed by using the photoresist composition of the experimental example; and

FIG. 15B illustrates an SEM photograph showing the photoresist pattern formed by using the photoresist composition of the comparative example.

### DETAILED DESCRIPTION OF THE EMBODIMENTS

Advantages and features of the embodiments and methods of accomplishing the same may be understood more readily by reference to the following description of exemplary embodiments and the accompanying drawings. The present invention may, however, be embodied in many different forms and should not be construed as being limited to the embodiments set forth herein. Rather, these exemplary embodiments are provided so that this disclosure will convey the concepts of the disclosure to those of ordinary skill in the art. Throughout the specification, like reference numerals in the drawings denote like elements.

It will be understood that when an element or a layer is referred to as being “on” or “connected to” another element or layer, it can be directly on or directly connected to the other element, or intervening elements may also be present. In contrast, when an element is referred to as being “directly on” or “directly connected to” another element, there are no intervening elements present. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures.

Embodiments of the invention are described herein with reference to plan and cross-section illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by a person of ordinary skill in the relevant art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a photoresist composition in accordance with an exemplary embodiment will be described.

Photoresist Composition

The photoresist composition includes an alkali-soluble novolac resin, a photosensitizer including a compound of Chemical Formula 1 and a solvent.

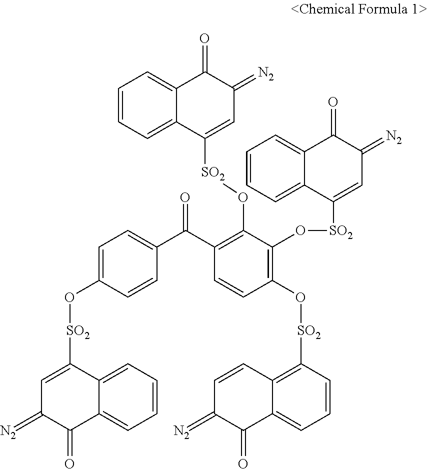

The alkali-soluble novolac resin is soluble in an alkali solution such as an aqueous alkali developing solution, and insoluble in water. The novolac resin may be obtained by an addition-condensation reaction of a phenolic compound and an aldehyde-based compound. Examples of the phenolic compound used in preparation of the novolac resin include but are not limited to phenol, o-cresol, m-cresol, p-cresol, 2,5-xylenol, 3,5-xylenol, 3,4-xylenol, 3,5-trimethylphenol, 4-t-butylphenol, 2-t-butylphenol, 3-t-butylphenol, 3-ethylphenol, 2-ethylphenol, 4-ethylphenol, 3-methyl-6-t-butylphenol, 4-methyl-2-t-butylphenol, 2-naphthol, 1,3-dihydroxynaphthalene, 1,7-dihydroxynaphthalene, 1,5-dihydroxynaphthalene and the like. These materials can be used singly or in combination.

Examples of the aldehyde-based compound used in preparation of the novolac resin include but are not limited to formaldehyde, paraformaldehyde, acetaldehyde, propylaldehyde, benzaldehyde, phenylaldehyde, α- and β-phenylpropylaldehyde, o-, m- and p-hydroxy benzaldehyde, glyoxal, o- and p-methylbenzaldehyde, and the like. These materials can be used singly or in combination.

The addition-condensation reaction of the phenolic compound and the aldehyde-based compound for preparation of the novolac resin may be carried out by a general method in the presence of an acid catalyst. In this case, for example, meta-cresol (m-cresol) and para-cresol (p-cresol) may be used as the phenolic compound. In this case, the m-cresol tends to increase the photosensitivity of the photoresist composition. On the other hand, the p-cresol tends to decrease the photosensitivity of the photoresist composition. Accordingly, the contents of m-cresol and p-cresol included in the novolac resin need to be appropriately adjusted. That is, a mixing ratio of the meta-cresol to the para-cresol may be 40:60 to 60:40 so as to appropriately maintain the photosensitivity of the photoresist composition.

The reaction temperature may be about 60° C. to 250° C., and the reaction time may be about 2 to 30 hours. As examples of the acid catalyst, there are an organic acid such as salicylic acid, formic acid, trichloroacetic acid and p-toluenesulfonic acid; an inorganic acid such as hydrochloric acid, sulfuric acid, perchloric acid and phosphoric acid; a divalent metal salt such as zinc acetate and magnesium acetate; and the like.

The addition-condensation reaction of the phenolic compound and the aldehyde-based compound for preparation of the novolac resin may be carried out in a suitable solution or bulk. The average molecular weight of the novolac resin prepared by the addition-condensation reaction may have a monodisperse polystyrene-equivalent weight-average molecular weight ranging from 2,000 to 50,000, which is measured by gel-permeation chromatography (GPC).

The alkali-soluble novolac resin may be present in an amount of 5 to 15 wt % with respect to weight of the total photoresist composition. If the content of the alkali-soluble novolac resin is smaller than 5 wt %, a development margin or a film remaining rate may be reduced, or heat resistance may deteriorate. If the content of the alkali-soluble novolac resin is larger than 15 wt %, sensitivity in forming a photoresist pattern may be reduced, or the obtained photoresist pattern may be damaged.

The compound of Chemical Formula 1 serves as a photosensitizer in the photoresist composition.

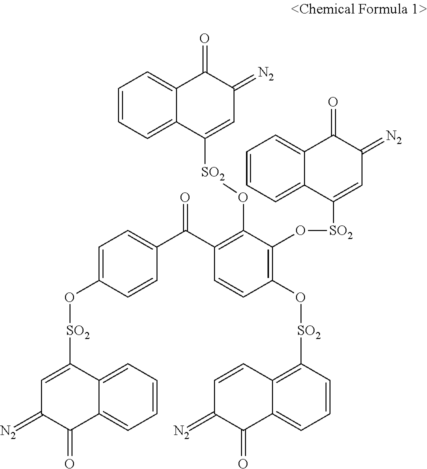

The compound of Chemical Formula 1 is formed by a condensation reaction between a compound of Chemical Formula 2 and a compound of Chemical Formula 3.

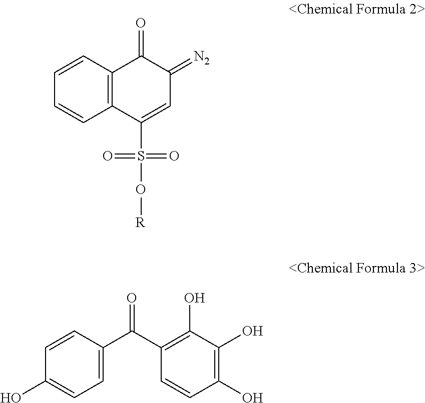

The compound of Chemical Formula 2 may be, for example, naphthoquinone 1,2-diazide-4-sulfonylchloride, or R may be a hydrogen atom, an alkyl group having a carbon number of 1 to 4, an alkenyl group having a carbon number of 2 to 4, a cycloalkyl group having a carbon number of 3 to 8, or an allyl group having a carbon number of 6 to 12.

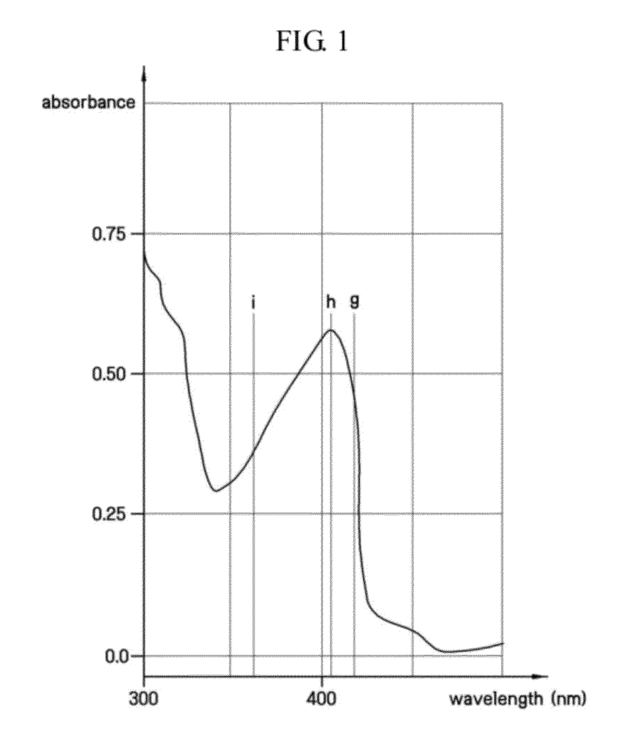

FIG. 1 illustrates the absorbance of the compound of Chemical Formula 2 as a function of wavelength band. Referring to FIG. 1, the compound of Chemical Formula 2 has the highest absorbance in h-line light having a wavelength of 405 nm. That is, the absorbance of the compound of Chemical Formula 2 has the highest level in h-line light having a wavelength of 405 nm rather than i-line or g-line light. Accordingly, because the compound of Chemical Formula 2 can absorb h-line light having a wavelength of 405 nm relatively efficiently, it can maintain high sensitivity in h-line light having a wavelength of 405 nm.

The compound of Chemical Formula 1 has excellent absorbance characteristics for h-line light in the same manner as the compound of Chemical Formula 2. Thus, the addition-condensation reaction between the compound of Chemical Formula 2 and the compound of Chemical Formula 3, does not cause a transformation of a functional group that limits the excellent absorbance for h-line light. Further, the photoresist composition including the photosensitizer containing the compound of Chemical Formula 1 can have excellent absorbance for h-line light having a wavelength of 405 nm.

The compound of Chemical Formula 3 may be 2,3,4,4′-tetrahydroxybenzophenone containing four hydroxyl groups (—OH). The compound of Chemical Formula 3 may increase absorbance for h-line light having a wavelength of 405 nm in digital exposure in cooperation with the compound of Chemical Formula 2. Accordingly, it is possible to form a photoresist pattern having high resolution by using a digital exposure device.

As described above, the addition-condensation reaction between the compound of Chemical, Formula 2 and the compound of Chemical Formula 3 is carried out at room temperature in presence of an acid catalyst for preparation of the compound of Chemical Formula 1. In this case, for example, —OR of Chemical Formula 2 and hydrogen (—H) of a hydroxyl group (—OH) of Chemical Formula 3 are combined with each other and removed. Accordingly, Chemical Formula 2 and Chemical Formula 3 may form an ester (—O—) combination. In this case, because the compound of Chemical Formula 3 includes four hydroxyl groups (—OH), each of the hydroxyl groups is combined with the compound of Chemical Formula 2, thereby forming the compound of Chemical Formula 1 including four ester (—O—) combinations.

Meanwhile, the photosensitizer containing the compound of Chemical Formula 1 may be present in an amount of 1 to 10 wt % with respect to the total weight of the photoresist composition. If the content of the photosensitizer is smaller than 1 wt %, the photoresist composition may have a reduced resolution for h-line light having a wavelength of 405 nm. Accordingly, the rate of the development of the photoresist pattern may be reduced, and a photoresist pattern having low uniformity may be formed. If the content of the photosensitizer is larger than 10 wt %, the critical dimension CD of the photoresist pattern may be excessively large as compared to a CD of the design.

Any solvent capable of dissolving the novolac resin and the compound of Chemical Formula 1 into a solution form may be employed. Typically, a solvent which is evaporated at an appropriate drying rate to form a uniform and flat photoresist film is used.

Example of the solvent include, but are not limited to, glycol ether ester such as ethyl cellosolve acetate, methyl cellosolve acetate, propylene glycol monomethyl ester acetate, and propylene glycol monoethyl ester acetate; glycol ether such as ethyl cellosolve, methyl cellosolve, propylene glycol monomethyl ether, and propylene glycol monoethyl ether; ester such as ethyl acetate, butyl acetate, amyl acetate and ethyl pyruvate; ketone such as acetone, methyl isobutyl ketone, 2-heptone and cyclohexanone; cyclic ester such as γ-butyrolacetone; and the like. These materials can be used singly or in combination.

The photoresist composition in accordance with an exemplary embodiment may further include a surfactant, an adhesive enhancer, a plasticizer, a sensitizer, and other resin components selectively if necessary.

The surfactant may function to improve the efficiency of coating or developing the photoresist composition. The surfactant may include, for example, polyoxyethylene octylphenyl ether, polyoxyethylene nonylphenyl ether, F171, F172, F173 (product name: Dainippon Ink and Chemicals (DIC) Inc.), FC430, FC431 (product name: Sumitomo 3-M Co. Ltd.), F-477 (product name: DIC Inc.), KP341 (product name: Shinwol Chemical, Co. Ltd.) or the like.

The adhesive enhancer is used to improve adhesivity between the substrate and photoresist pattern. The adhesive enhancer may employ a silane coupling agent having a reactive substituent, e.g., a carboxyl group, a methacrylic group, an isocyanate group and an epoxy group. Examples of the adhesive enhancer include, but are not limited to, γ-methacryloxypropyltrimethoxysilane, vinyltriacetoxysilane, vinyltrimethoxysilane, γ-isocyanatepropyltriethoxysilane, γ-glycidoxypropyltrimethoxysilane, β-(3,4-epoxycyclohexyl)ethyltrimethoxysilane and the like. These materials can be used singly or in combination.

Hereinafter, a method of forming a pattern in accordance with an exemplary embodiment will be described with reference to the drawings.

Method of Forming Pattern

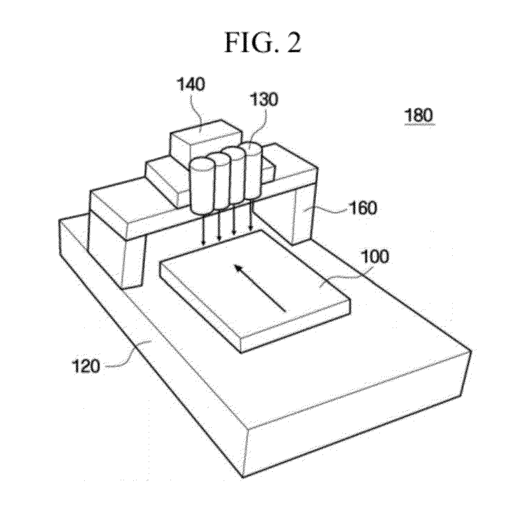

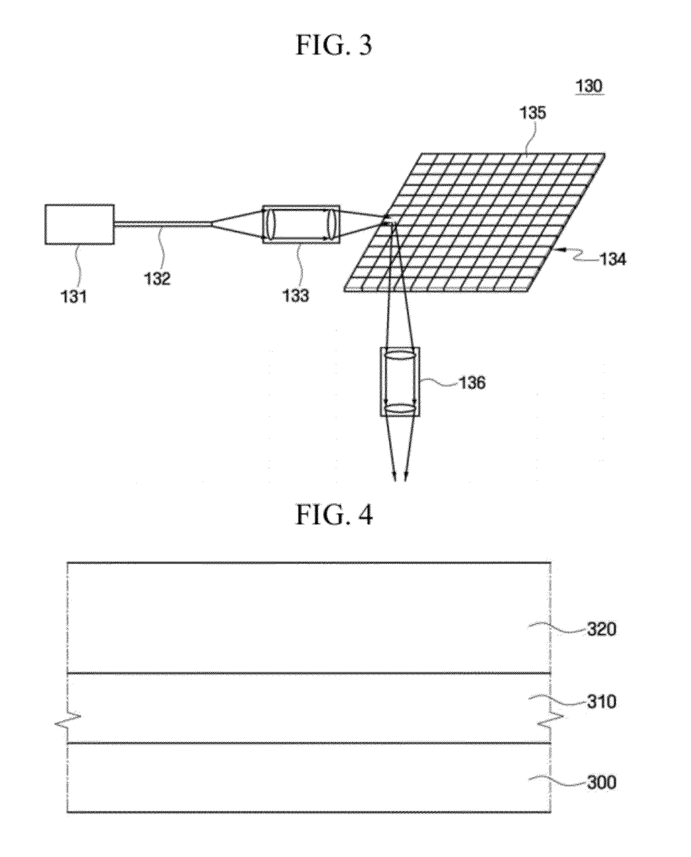

First, a configuration of a digital exposure device used in forming a pattern in accordance with an exemplary embodiment will be described with reference to FIGS. 2 and 3. FIG. 2 illustrates a perspective view showing a digital exposure device used in forming a pattern in accordance with an exemplary embodiment. FIG. 3 is a block diagram showing a specific configuration of an exposure head shown in FIG. 2.

A digital exposure device 180 includes a stage 120 for transferring a substrate 100, exposure heads 130 for supplying light to the substrate 100, a first supporting unit 140 for supporting the exposure heads 130, and a second supporting unit 160 for maintaining a distance between the substrate 100 and the exposure heads 130.

The stage 120 transfers the substrate 100 such that the substrate 100 on which a pattern will be formed passes through the light supplied from the exposure heads 130. In this case, the stage 120 transfers the substrate 100 for an appropriate period of time such that the photoresist on the substrate 100 is exposed to the light supplied from the exposure heads 130 for the appropriate duration.

The first supporting unit 140 fixes the exposure heads 130. Further, the first supporting unit 140 may be provided with a connection device for supplying pattern data to the exposure heads 130.

The second supporting unit 160 is formed such that the first supporting unit 140 is stably installed on the second supporting unit 160. The second supporting unit 160 is formed to extend by a predetermined distance from the stage 120, such that the substrate 100 passes through the light supplied from the exposure heads 130.

The exposure heads 130 may supply incident light to particular spaces selected according to the pattern data. For this, the exposure heads 130 are provided with a digital micromirror device (hereinafter, referred to as “DMD”) 134.

The DMD 134 includes a controller having a data processor and a mirror driving controller. The mirror driving controller generates a control signal for driving and controlling each of the micromirrors 135 for each of the exposure heads 130 according to the pattern data inputted from the data processor in a region to be controlled by the DMD 134. The mirror driving controller also controls an angle of a reflection plane of each of the micromirrors 135 for each of the exposure heads 130 based on a control signal generated by the data processor. The exposure heads 130 may further include at least one laser diode 131 for generating light to be provided to the DMD 134, and at least one optical fiber 132 for supplying light generated in the laser diode 131 to the DMD 134. The laser diode 131 may be positioned outside the exposure heads 130. If the laser diode 131 is outside of the exposure heads 130, the light generated in the laser diode 131 is supplied to the exposure heads 130 through optical fiber 132.

A first lens system 133 is positioned at a light incident side of the DMD 134. The first lens system 133 condenses the light supplied from the laser diode 131 via the optical fiber 132 and supplies the condensed light to the DMD 134. The first lens system 133 converts light emitted from an end of the optical fiber 132 into collimated light. The first lens system 133 includes lenses for correcting the collimated light to make the light quantity distribution uniform. The first lens system 133 also includes a condenser lens for condensing the corrected light onto the DMD 134.

The DMD 134 includes a plurality of the micromirrors 135 arranged in a grid pattern. Each of the micromirrors 135 may be moved so as to be inclined at an angle of, e.g., ±10 degrees. A material having high reflectivity, e.g., aluminum, is deposited on the surfaces of the micromirrors 135. The reflectivity of the micromirrors 135 may be at least 90%. Accordingly, the light incident onto the DMD 134 can be reflected in the inclination direction of each of the micromirrors 135 by controlling the inclination of the micromirrors 135 according to the pattern data.

A second lens system 136 for forming an image from light reflected from the DMD 134 onto the substrate is positioned at a light reflection side of the DMD 134. The second lens system 136 is positioned between the DMD 134 and the substrate to condense and supply the light reflected from the DMD 134 onto the substrate 100.

By the aforementioned method, a specific region of the photoresist film formed on the substrate 100 can be exposed to light by using the exposure heads 130 of the digital exposure device 180 without an additional mask.

Next, a method of forming a pattern in accordance with an exemplary embodiment will be described with reference to FIGS. 4 to 7. FIGS. 4 to 7 illustrate cross sectional views showing the steps of the method of forming a pattern in accordance with an exemplary embodiment.

Referring to FIG. 4, first, a substrate 300 on which a pattern forming film 310 is formed is prepared. A cleaning process for removing moisture or contaminants existing on the surface of the pattern forming film 310 or the substrate 300 may be selectively performed.

Then, a photoresist film 320 is formed by coating the photoresist composition, which includes an alkali-soluble novolac resin, a photosensitizer including a compound of Chemical Formula 1 and a solvent, on the pattern forming film 310. For example, the photoresist composition can be coated by using a spraying method, a roll coating method, a spin coating method or the like.

Because the photoresist composition is substantially the same as the photoresist composition in accordance with exemplary embodiments as described above, description thereof will be omitted here.

After the photoresist film 320 is formed, a first baking process may be performed by heating the substrate 300 having the photoresist film 320. For example, the first baking process may be performed at a temperature ranging from, for example, about 70° C. to about 130° C. As the first baking process is performed, the solvent is removed and adhesion between the pattern forming film 310 and the photoresist film 320 may be improved.

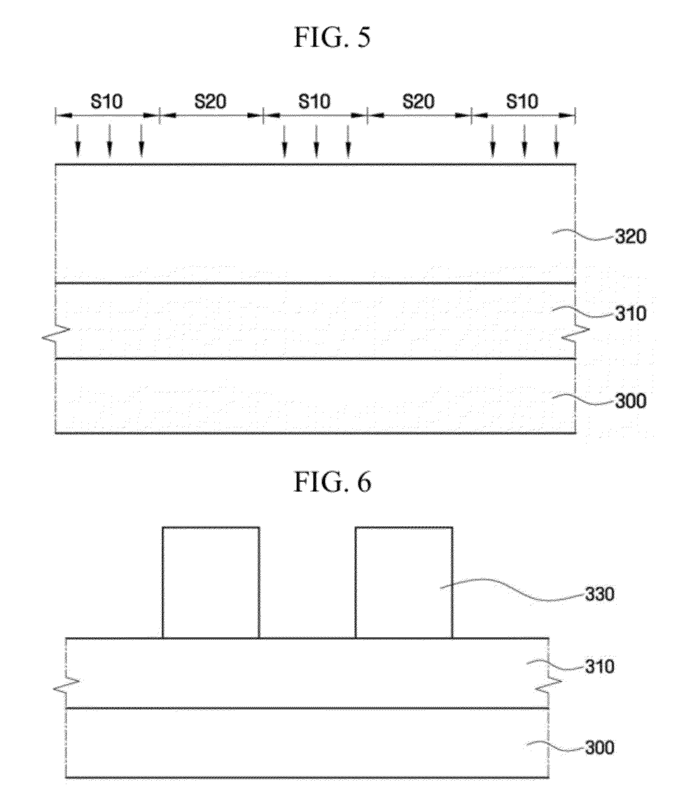

Referring to FIG. 5, the substrate 300 is exposed to light. Specifically, the substrate 300 is placed on the stage 120 of the digital exposure device 180 shown in FIG. 2, and light is irradiated onto the substrate 300 for a predetermined period of time. The light emitted from the exposure heads 130 is irradiated onto a region S10 where a pattern is not formed, and is not irradiated onto a region S20 where a pattern is formed. The light causes the composition and structure of the region of the photoresist film 320 onto which the light is irradiated to change so that it may be dissolved by a developing solution. The light irradiated by the digital exposure device 180 may be h-line light having a wavelength of about 405 nm.

Referring to FIG. 6, a photoresist pattern 330 is formed by removing the region onto which light was irradiated (corresponding to the region S10) from the photoresist film 320 by using a developing solution.

Because the photoresist composition in accordance with an exemplary embodiment is a positive photoresist composition, a portion the photoresist composition onto which light is irradiated is removed. Conventional, well-known developing solutions may be used. For example, tetramethylammonium hydroxide (TMAH) or the like may be used as the developing solution.

A second baking process may be performed on the developed photoresist pattern 330.

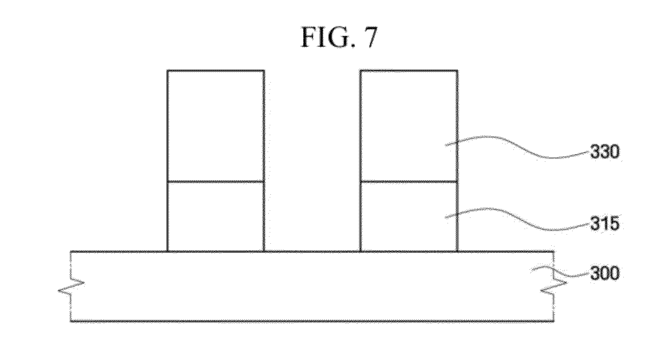

Subsequently, referring to FIG. 7, a pattern 315 may be formed by etching the pattern forming film 310 using the photoresist pattern 330 as an etching mask.

Hereinafter, a method of fabricating a thin film transistor substrate in accordance with an exemplary embodiment will be described in detail with reference to the accompanying drawings.

Method of Fabricating Thin Film Transistor

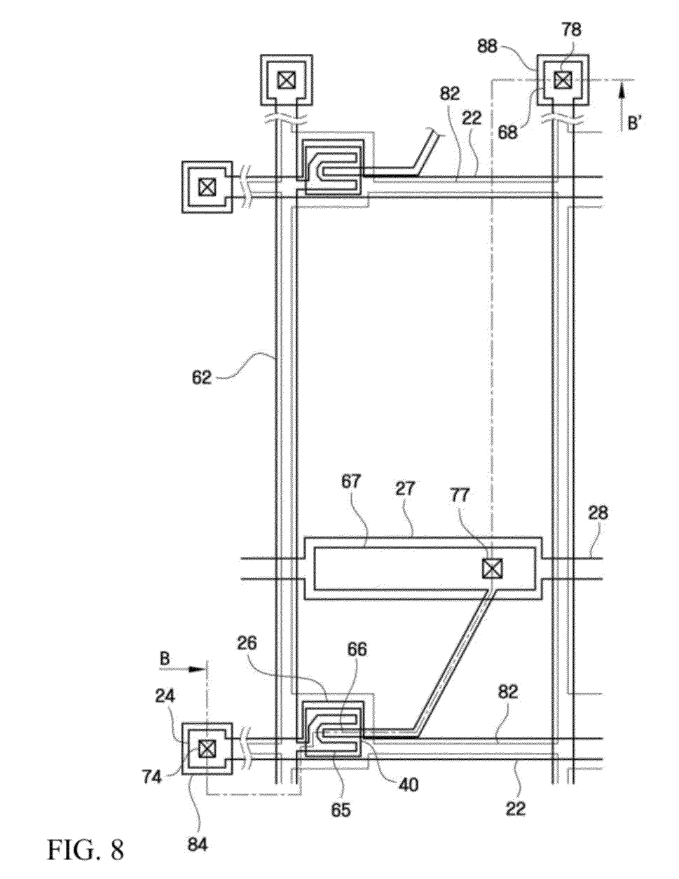

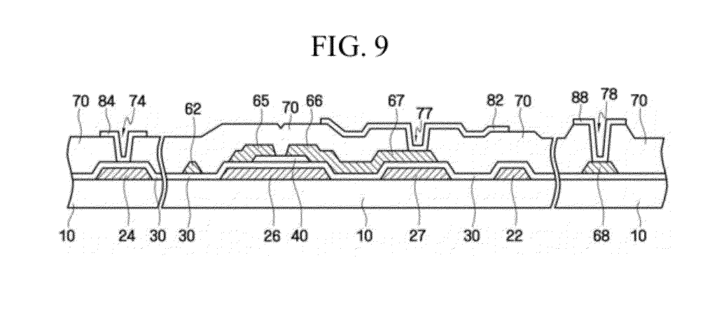

First, a structure of a thin film transistor substrate fabricated by the fabricating method in accordance with an exemplary embodiment will be described with reference to FIGS. 8 and 9. FIG. 8 illustrates a layout of the thin film transistor substrate fabricated by the fabricating method. FIG. 9 illustrates a cross sectional view of the thin film transistor substrate, which is taken along line B-B′ of FIG. 8.

A gate wiring for transmitting a gate signal is formed on an insulating substrate 10. The gate wiring 22, 24, 26, 27 and 28 includes a gate line 22 extending in a horizontal direction, a gate end portion 24 connected to the end of the gate line 22 to transmit a gate signal to be applied to the gate line 22, a gate electrode 26 connected to the gate line 22 and formed in a protruded shape, and a sustain electrode 27 and a sustain electrode line 28 formed in parallel with the gate line 22. The sustain electrode line 28 is formed across a pixel region in a horizontal direction. The sustain electrode 27 has a width that is larger than that of the sustain electrode line 28, and is connected to the storage electrode line 28. The sustain electrode 27 overlaps with a drain electrode extension portion 67 connected to a pixel electrode 82, which will be described later, thereby forming a storage capacitor to improve the charge storage capacity of a pixel. The shape and arrangement of the sustain electrode 27 and the sustain electrode line 28 may be modified in various ways. If, however, the storage capacitance generated by the overlapping of just the pixel electrode 82 and the gate line 22 is sufficient, the sustain electrode 27 and the sustain electrode line 28 may be omitted.

The gate wiring 22, 24, 26 and 27 may be formed of aluminum-based metal such as, for example, aluminum (Al) and an aluminum alloy, silver-based metal such as silver (Ag) and a silver alloy, copper-based metal such as copper (Cu) and a copper alloy, molybdenum-based metal such as molybdenum (Mo) and a molybdenum alloy, chromium (Cr), titanium (Ti), tantalum (Ta) or the like. Further, the gate wiring 22, 24, 26 and 27 may have a multilayer structure including two conductive films (not shown) having different physical properties. One of the conductive films may be formed of low resistivity metal, e.g., aluminum-based metal, silver-based metal and/or copper-based metal, to reduce signal delay or voltage drop of the gate wiring 22, 24, 26 and 27. The other one of the conductive films may be formed of a different material, e.g., molybdenum-based metal, chromium (Cr), titanium (Ti), tantalum (Ta) or the like, having excellent contact characteristics with, particularly, indium tin oxide (ITO) and indium zinc oxide (IZO). Examples of such combination may include, but are not limited to, a structure including a lower film of chromium and an upper film of aluminum, a structure including a lower film of aluminum and an upper film of molybdenum, and the like. However, the present disclosure is not limited thereto, and the gate wiring 22, 24, 26 and 27 may be formed of various metals and conductors.

The sustain electrode line 28 may have the same structure as the gate wiring 22, 24, 26 27.

A gate insulating film 30 made of, e.g., silicon nitride (SiNx) may be formed on the substrate 10 and the gate wiring 22, 24, 26, 27 and 28.

A semiconductor layer 40 made of a semiconductor such as hydrogenated amorphous silicon, polycrystalline silicon or the like may be formed on the gate insulating film 30 of the gate electrode 26. The semiconductor layer 40 may have various shapes such as an insular shape or a linear shape.

The data wiring 62, 65, 66, 67 and 68 may be formed on the semiconductor layer 40 and the gate insulating film 30. The data wiring 62, 65, 66, 67 and 68 may include a data line 62 formed in a vertical direction so as to intersect the gate line 22, thereby defining a pixel, a source electrode 65 that is branched off from the data line 62 to extend to the top of the semiconductor layer 40, a data end portion 68 connected to one end of the data line 62 and to which an image signal is applied, a drain electrode 66 separated from the source electrode 65 and formed on the semiconductor layer 40 to face the source electrode 65 around the gate electrode 26, and the drain electrode extension portion 67 extending from the drain electrode 66 and having a large area overlapping with the sustain electrode 27.

The data wiring 62, 65, 66, 67 and 68 is preferably formed of fire-resistant metal such as, for example, chromium (Cr), molybdenum-based metal, tantalum (Ta) and titanium (Ti). The data wiring 62, 65, 66, 67 and 68 may have a multilayer structure including a lower film (not shown) made of, e.g., fire-resistant metal and an upper film (not shown) made of a low resistivity metal formed on the lower film. Examples of the multilayer structure include but are not limited to a triple layer structure including molybdenum-aluminum-molybdenum films in addition to a double layer structure including a lower film of chromium and an upper film of aluminum, or a lower film of aluminum and an upper film of molybdenum as described above.

The source electrode 65 at least partially overlaps with the semiconductor layer 40. The drain electrode 66 at least partially overlaps with the semiconductor layer 40 so as to face the source electrode 65 around the gate electrode 26.

The drain electrode extension portion 67 is formed so that it overlaps with the sustain electrode 27, thereby forming a storage capacitor. The gate insulating film 30 is interposed between the drain electrode extension portion 67 and the sustain electrode 27. If the sustain electrode 27 is not formed, the drain electrode extension portion 67 may be omitted.

A passivation film 70 may be formed on the data wiring 62, 65, 66, 67 and 68 and the exposed semiconductor layer 40. For example, the passivation film 70 may be formed of an organic material having excellent planarization characteristics and photosensitivity, a low-k insulating material formed by plasma enhanced chemical vapor deposition (PECVD), such as a-Si:C:O and a-Si:O:F, or an inorganic material such as silicon nitride (SiNx). Further, if the passivation film 70 is formed from an organic material, an insulating film (not shown) made of silicon nitride (SiNx) or silicon oxide (SiO₂) may be additionally formed below the organic film to prevent the passivation film 70 from being in contact with the organic material at a portion where the semiconductor layer 40 is exposed, between the source electrode 65 and the drain electrode 66.

Contact holes 77 and 78 are formed in the passivation film 70 to expose the drain electrode extension portion 67 and the data end portion 68. Also, a contact hole 74 is formed in the passivation film 70 and the gate insulating film 30 to expose the gate end portion 24. The pixel electrode 82, which is located in the pixel, is formed on the passivation film 70. The pixel electrode 82 is electrically connected to the drain electrode extension portion 67 through the contact hole 77. The pixel electrode 82 to which a data voltage is applied generates an electrical field with a common electrode of an upper display substrate (not shown), thereby determining the arrangement of liquid crystal molecules in a liquid crystal layer between the pixel electrode 82 and the common electrode. A subsidiary gate end portion 84 and a subsidiary data end portion 88 are formed on the passivation film 70 so as to be connected to the gate end portion 24 and the data end portion 68 through the contact holes 74 and 78, respectively. The pixel electrode 82 and the subsidiary gate and data end portions 84 and 88 may be formed of a transparent conductor such as, for example, indium tin oxide (ITO) or indium zinc oxide (IZO).

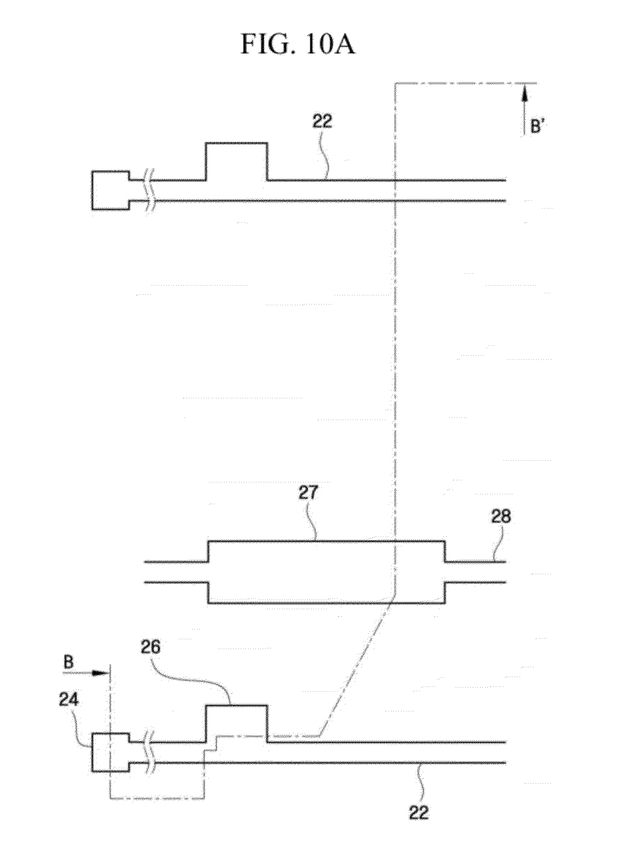

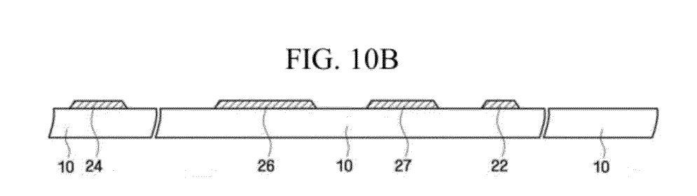

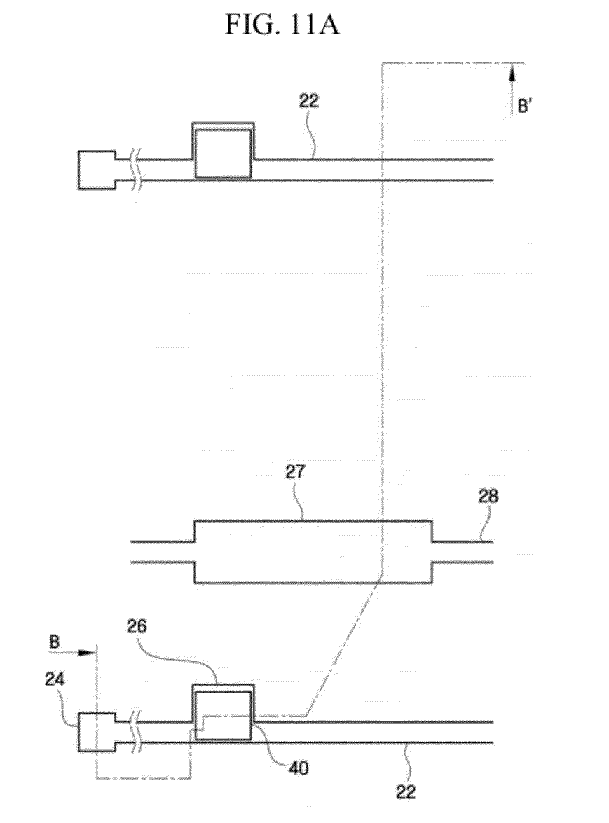

Hereinafter, a method of fabricating a display device in accordance with an exemplary embodiment will be described in detail with reference to FIGS. 8 to 14B. FIGS. 10A to 14B illustrate cross sectional views for explaining a method of fabricating a display device of FIG. 8.

First, as shown in FIGS. 10A and 10B, the gate wiring 22, 24, 26, 27 and 28 is formed on the substrate 10. A sputtering method may be used to form a conductive film for gate wiring. The gate wiring 22, 24, 26, 27 and 28 may be patterned by wet etching or dry etching. In the case of wet etching, an etching solution of, for example, phosphoric acid, nitric acid, acetic acid or the like may be used. Further, in case of dry etching, a chlorine-based etching gas such, for example, as Cl₂ and BCl₃ may be used.

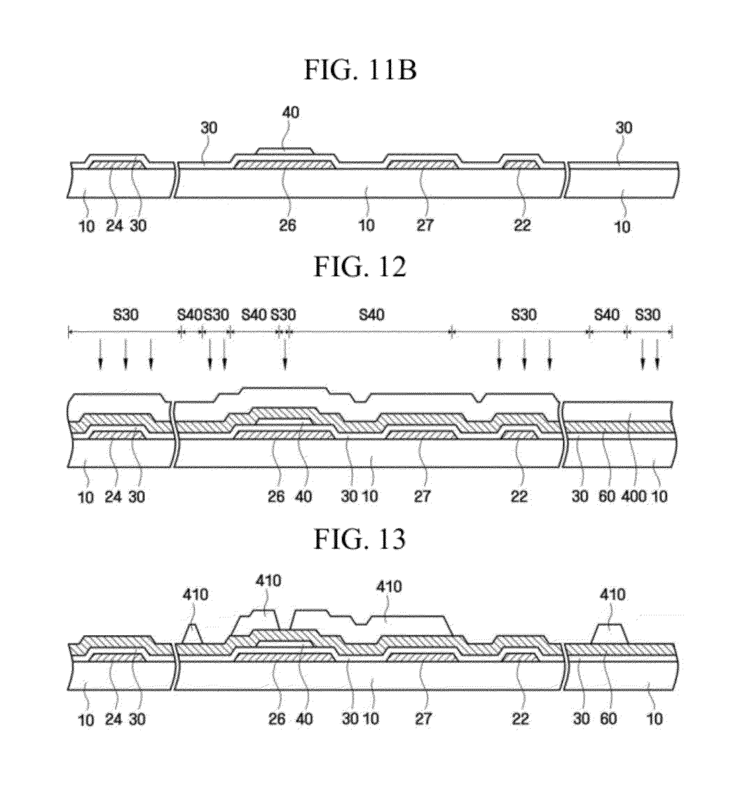

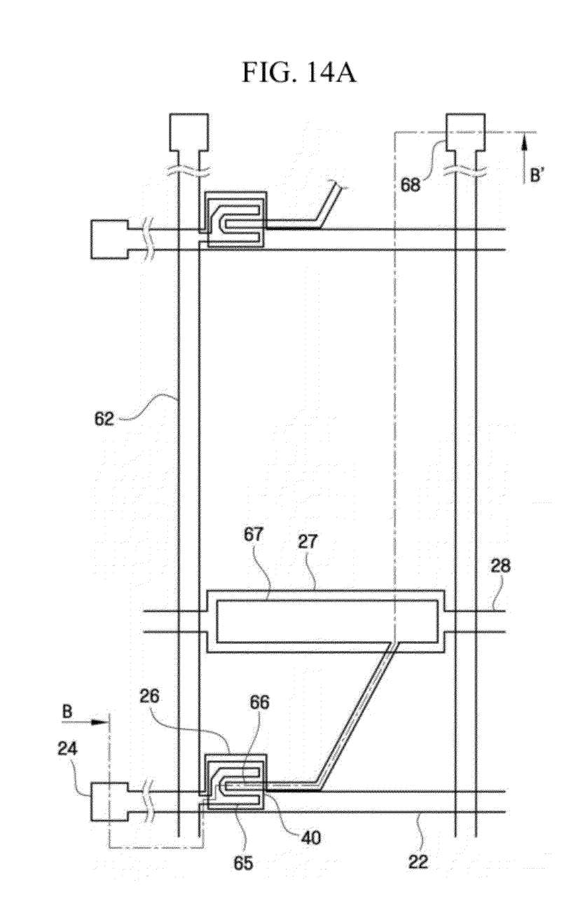

Subsequently, referring to FIGS. 11A and 11B, the gate insulating film 30 made of silicon nitride or the like is formed on the substrate 10 and the gate wiring 22, 24, 26, 27 and 28 by, e.g., plasma enhanced chemical vapor deposition (PECVD) or reactive sputtering. Then, the semiconductor layer 40 is formed on the gate insulating film 30.

Subsequently, referring to FIG. 12, a conductive film 60 for data wiring is formed on the gate insulating film 30 and the semiconductor layer 40. Then, a photoresist film 400 is formed by coating a photoresist composition, which includes an alkali-soluble novolac resin, a photosensitizer including a compound of Chemical Formula 1 and a solvent, onto the conductive film 60. For example, the photoresist film 400 may be coated by using a spraying method, a roll coating method, a spin coating method or the like.

Because the photoresist composition and a method of forming a photoresist pattern are substantially the same as the photoresist composition and the pattern forming method in accordance with exemplary embodiments of the present invention as described above, description thereof will be omitted.

The substrate 10 on which the photoresist film 400 is formed is exposed to light. The light emitted from the exposure heads 130 (see FIG. 2) is irradiated onto a region S30 where the data wiring 62, 65, 66, 67 and 68 is not formed, and is not irradiated onto a region S40 where the data wiring 62, 65, 66, 67 and 68 is formed.

Subsequently, referring to FIG. 13, a photoresist pattern 410 is formed by removing the region of the photoresist film 400 onto which light was irradiated by using a developing solution.

Subsequently, referring to FIGS. 14A and 14B, the data wiring 62, 65, 66, 67 and 68 may be formed by etching the conductive film 60 for data wiring while using the photoresist pattern 410 as a mask.

Subsequently, referring to FIG. 9, the passivation film 70 is formed by, for example, PECVD or reactive sputtering. Then, the contact holes 74, 77 and 78 that expose the gate end portion 24, the drain electrode extension portion 67 and the data end portion 68, respectively, are formed by patterning the passivation film 70 together with the gate insulating film 30 by photolithography.

Subsequently, referring to FIG. 9, a transparent conductive film is deposited, and photolithography is performed to form the pixel electrode 82, which is connected to the drain electrode 66 through the contact hole 77, and the subsidiary gate end portion 84 and the subsidiary data end portion 88, which are connected to the gate end portion 24 and the data end portion 68 through the contact holes 74 and 78, respectively.

Although the method of fabricating a thin film transistor substrate to form a data wiring using a photoresist pattern made of a photoresist composition has been described in this embodiment, the present disclosure is not limited thereto. For example, a semiconductor layer pattern or another electrode pattern of the thin film transistor substrate may be formed by using the photoresist pattern made of the photoresist composition in accordance with the exemplary embodiments of the present disclosure.

Hereinafter, an experimental example and a comparative example will be described.

### Experimental Example

A novolac resin having a weight-average molecular weight of 6,000 was prepared by a condensation reaction between formaldehyde and cresol monomer in which meta-cresol and para-cresol are mixed at a mixing ratio of 60:40 in the presence of an oxalic acid catalyst. Further, a photosensitizer was prepared by a condensation reaction between a compound of Chemical Formula 2, specifically and a compound of Chemical Formula 3 in the presence of an acid catalyst, specifically.

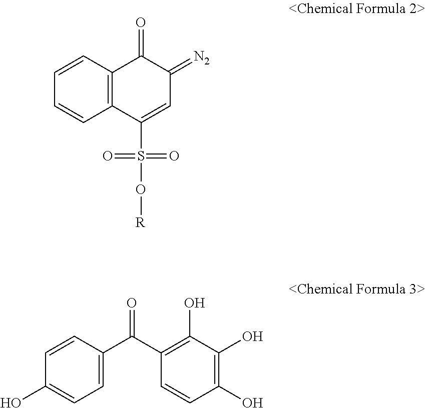

Accordingly, the compound of Chemical Formula 1 was prepared.

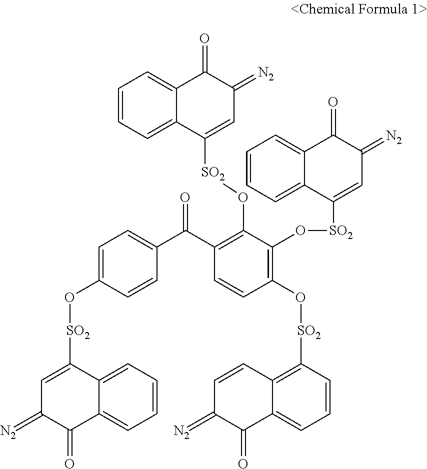

Thereafter, the photoresist composition was prepared by mixing an alkali-soluble novolac resin present in an amount of 10 wt %, a photosensitizer in an amount of 5 wt %, and a solvent present in an amount of 85 wt % (each as a percent of the total weight of the photoresist composition). In this case, for example, propylene glycol methyl ether acetate (PGMEA) may be used as the solvent.

### Comparative Example

The photoresist composition was prepared in the same manner as in the experimental example except that the photosensitizer used in the photoresist composition was naphthoquinone-1,2-diazide-5-sulfonyl chloride (at 5 wt % as a percent of the total weight of the composition) instead of the compound of Chemical Formula 1.

Evaluation of Photoresist Pattern

The photoresist pattern was formed by using the photoresist composition of the experimental example and the comparative example. Specifically, vacuum drying and prebaking were carried out after the photoresist composition of each of the experimental example and the comparative example was coated on the substrate. Then, the formed film was exposed to h-line light by using a digital exposure device. Then, the film was developed by an aqueous solution of 2.38 wt % tetramethylammonium hydroxide (TMAH) to remove the portions of the photoresist patterns that had been exposed to h-line light, and the developed patterned was subject to post baking.

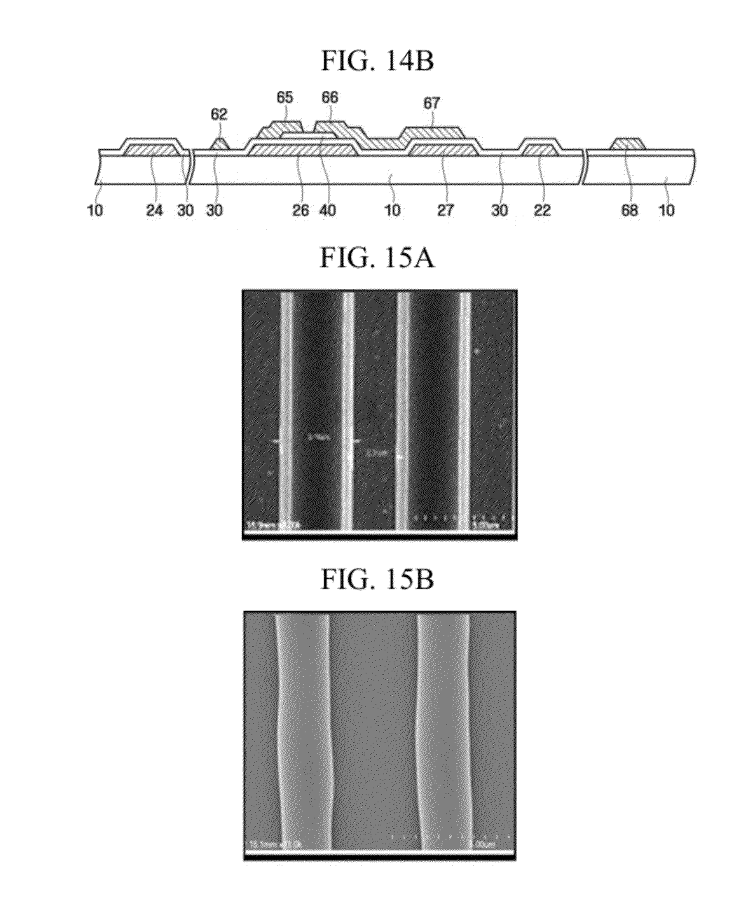

The pattern profile of the developed photoresist pattern was observed by a scanning electron microscope (SEM). FIG. 15A illustrates an SEM photograph showing the photoresist pattern formed by using the photoresist composition of the experimental example. FIG. 15B illustrates an SEM photograph showing the photoresist pattern formed by using the photoresist composition of the comparative example.

Generally, the photoresist pattern formed by exposure and development of the photoresist composition may have a first width and a second width having different sizes. In this case, if the first width is a maximum line width and the second line width is a minimum line width, an absolute value of a difference between the first and second widths is referred to as “line width roughness.” The line width roughness may be used as an indicator showing nonuniformity of the photoresist pattern. In this case, it is preferable that the line width roughness is equal to or smaller than 0.2. If a circuit pattern is formed by using the photoresist pattern having line width roughness exceeding 0.2 as a mask, a display device including the circuit pattern may have an unstable liquid crystal operation. Accordingly, a display device having a stain defect may be fabricated. Accordingly, the photoresist pattern should be formed to have line width roughness equal to or smaller than 0.2 in order to ensure an excellent display quality.

Referring to FIG. 15A, the photoresist pattern formed by digital exposure using the photoresist composition prepared in the experimental example had line width roughness of about 0.4. That is, referring to FIGS. 15A and 15B, it can be seen that when the photoresist pattern is formed by digital exposure using the photoresist composition in accordance with an exemplary embodiment, a photoresist pattern having an excellent pattern shape can be formed.

While the present disclosure references to exemplary embodiments, it will be understood by those of ordinary skill in the relevant art that various changes in form and detail may be made therein without departing from the spirit and scope of the present invention. The exemplary embodiments should be considered in a descriptive sense only and not for purposes of limitation.

What is claimed is:

1. A photoresist composition comprising:
an alkali-soluble novolac resin;
a photosensitizer including a compound of Chemical Formula 1; and
a solvent.

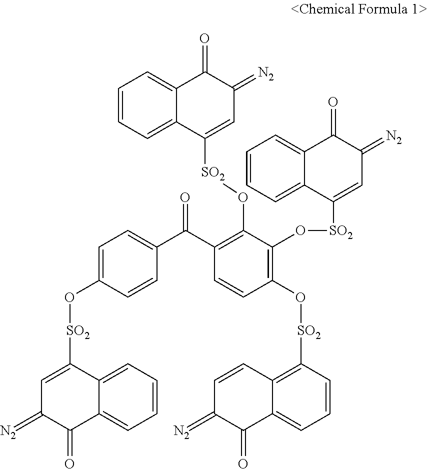

2. The photoresist composition of claim 1, wherein the compound of Chemical Formula 1 is formed by a condensation reaction between a compound of Chemical Formula 2 (where R is a hydrogen atom, an alkyl group having a carbon number of 1 to 4, an alkenyl group having a carbon number of 2 to 4, a cycloalkyl group having a carbon number of 3 to 8, or an allyl group having a carbon number of 6 to 12) and a compound of Chemical Formula 3.

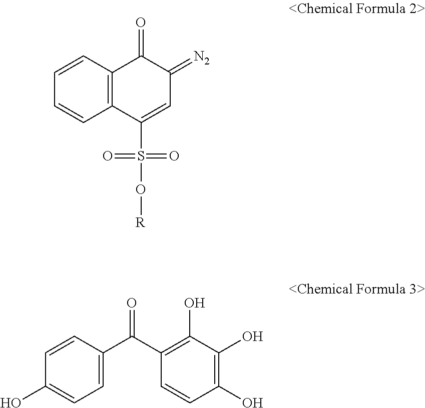

3. The photoresist composition of claim 1, wherein the photoresist composition contains the alkali-soluble novolac resin present in an amount of 5 to 15 wt %, the photosensitizer present in an amount of 1 to 10 wt % and a residual amount of the solvent.

4. The photoresist composition of claim 1, wherein the novolac resin includes meta-cresol and para-cresol and a mixing ratio of the meta-cresol to the para-cresol is in the range of 40:60 to 60:40.

5. The photoresist composition of claim 1, wherein the compound of Chemical Formula 1 absorbs h-line light having a wavelength of 405 nm.

6. The photoresist composition of claim 1, further comprising at least one selected from the group consisting of a surfactant, an adhesive enhancer, a plasticizer and a sensitizer.

7. The photoresist composition of claim 1, wherein the photoresist composition is of a positive type.

8. The photoresist composition of claim 1, wherein the alkali-soluble novolac resin has a monodisperse polystyrene-equivalent weight-average molecular weight ranging from 2,000 to 50,000.

9. A method of forming a pattern, comprising:
forming a photoresist film by coating a pattern formation film with a photoresist composition containing an alkali-soluble novolac resin, a photosensitizer including a compound of Chemical Formula 1, and a solvent;
exposing the photoresist film to light;
developing the photoresist film to form a photoresist pattern; and
patterning the pattern formation film using the photoresist pattern as an etching mask.

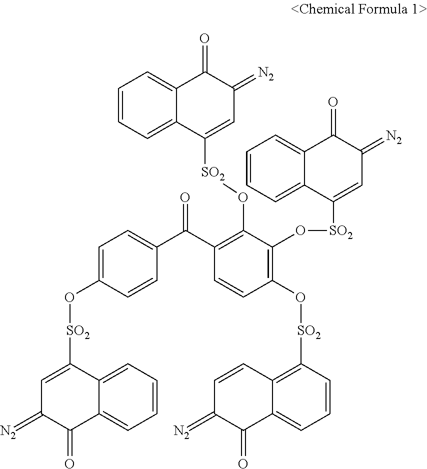

10. The method of claim 9, wherein the compound of Chemical Formula 1 is formed by a condensation reaction between a compound of Chemical Formula 2 (where R is a hydrogen atom, an alkyl group having a carbon number of 1 to 4, an alkenyl group having a carbon number of 2 to 4, a cycloalkyl group having a carbon number of 3 to 8, or an allyl group having a carbon number of 6 to 12) and a compound of Chemical Formula 3.

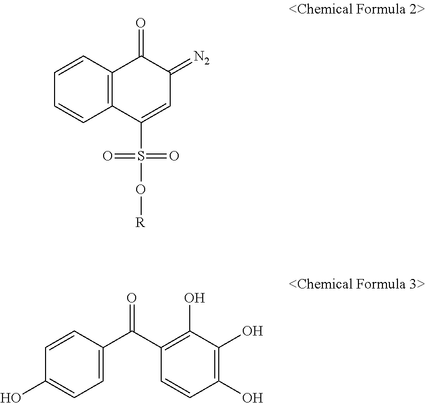

11. The method of claim 9, wherein the photoresist composition contains the alkali-soluble novolac resin present in an amount of 5 to 15 wt %, the photosensitizer present in an amount of 1 to 10 wt % and a residual amount of the solvent.

12. The method of claim 9, wherein the novolac resin includes meta-cresol and para-cresol and a mixing ratio of the meta-cresol to the para-cresol is in a range of 40:60 to 60:40.

13. The method of claim 9, wherein said exposing the photoresist film is performed by using a digital exposure device.

14. The method of claim 13, wherein the light used in exposing the photoresist film to light has a wavelength of 405 nm.

15. The method of claim 13, wherein the digital exposure device includes a digital micromirror device.

16. The method of claim 9, further comprising at least one selected from the group consisting of a surfactant, an adhesive enhancer, a plasticizer and a sensitizer.

17. The method of claim 9, wherein the photoresist pattern is formed in an area onto which light is not irradiated.

18. The method of claim 9, wherein the alkali-soluble novolac resin has a monodisperse polystyrene-equivalent weight-average molecular weight ranging from 2,000 to 50,000.

19. The method of claim 9, wherein the photoresist pattern includes a first width and a second width, and an absolute value of a difference between the first width and the second width is equal to or smaller than 0.2.
